(19) United States
(12) Patent Application Publication
(10) Pub. No.: US 2025/0311469 A1
(43) Pub. Date: Oct. 2, 2025

(54) STRAIN ISOLATION GAP GATE STACK FOR SEMICONDUCTOR QUANTUM DEVICES

(71) Applicant: International Business Machines Corporation, Armonk, NY (US)

(72) Inventors: Felix Julian Schupp, Zurich (CH); Matthias Mergenthaler, Zurich (CH); Nico Hendrickx, Adliswil (CH); Leonardo Massai, Zurich (CH); Stephan Paredes, Zurich (CH)

(21) Appl. No.: 18/620,942

(22) Filed: Mar. 28, 2024

(51) Int. Cl. H01L 31/0352; G06N 10/40; H01L 31/0224; H01L 31/028

(52) U.S. Cl. CPC H10F 77/1433; G06N 10/40; H10F 77/122; H10F 77/206

(57) ABSTRACT

A semiconductor structure includes a semiconductor substrate; a gate electrode separated from the semiconductor substrate by a strain isolation gap; and a quantum dot region formed in the substrate underneath the gate electrode. The quantum dot region is configured to form a quantum dot upon energization of the gate electrode, and the quantum dot is configured to host a spin.

### BACKGROUND

The present invention relates to the electrical, electronic, and computer arts, and more specifically, to semiconductor quantum devices that are used in quantum computing.

Quantum circuits form multiple localized quantum states that can be used as qubits if the quantum states form two-level systems where one level corresponds to a bit value 1 and the other to a bit value 0. The quantum circuits facilitate the execution of an algorithm by delivering the signals needed to initialize, manipulate and entangle the qubits as well as read-out the result as a bit string. In the specific case of spin qubits, the qubits can be manipulated using a superconducting current-carrying wire next to the quantum dot to generate precisely controlled magnetic fields. Alternatively, periodic changes in the applied electrical potential (e.g., through microwaves applied to a nearby gate-electrode), can be used to periodically apply changing electric fields that couple to the charge and cause occupation of different orbitals. Through either the spin-orbit effect or movement in an inhomogeneous magnetic field, this periodic change in the applied electrical potential can then drive the spin and control the qubit.

Quantum circuits are sensitive to their environments and very specific operating conditions are typically imposed to maintain the coherence of the qubits. For example, solid-state quantum computing architectures rely on operation at very low temperatures, typically near absolute zero (−273.15° C. or 0 K). This is because the thermal motion of atoms can interfere with the coherence of the qubits. Various cooling methods are used to achieve these low temperatures, such as dilution refrigerators or slightly warmer Helium-based systems. Quantum circuits typically are shielded from stray magnetic fields from outside the cryostat, as even weak stray magnetic fields from outside the cryostat can disrupt the delicate quantum states of the qubits. Quantum circuits generally operate in a near-vacuum environment.

For clarity, it should be noted that typically, there is an external field to the chip that is intentionally applied using coils in the cryostat. Another type of field is a field from a magnetic structure on the chip, so that field is external to the substrate but is on the chip. Then, there are other fields from outside (that are undesirable). Fields from outside the cryostat are “stray magnetic fields from outside the cryostat”; the fields from the coils are “external fields” and the fields from a structure on the chip are called “fields from on-chip micro- or nano-magnets.”

### SUMMARY

Principles of the invention provide techniques for a strain isolation gap gate stack for semiconductor quantum devices. In one aspect, an exemplary semiconductor structure includes a semiconductor substrate; a gate electrode separated from the semiconductor substrate by a strain isolation gap; and a quantum dot region formed in the substrate underneath the gate electrode. The quantum dot region is configured to form a quantum dot upon energization of the gate electrode. The quantum dot is configured to host a spin.

In another aspect, an exemplary quantum processing unit includes an array of quantum semiconductor structures. Each quantum semiconductor structure includes a semiconductor substrate; a gate electrode separated from the semiconductor substrate by a strain isolation gap; and a quantum dot region formed in the substrate underneath the gate electrode. The quantum dot region is configured to form a quantum dot upon energization of the gate electrode. The quantum dot is configured to host a spin. The exemplary quantum processing unit also includes a voltage source coupled to the gate electrode of each quantum semiconductor structure; and a controller coupled to the voltage source. The controller is configured to cause the voltage source to selectively energize the gate electrode of each quantum semiconductor structure.

In still another aspect, an exemplary method of providing strain relief in a quantum processing unit includes: providing a chip with a gate stack having at least one gate electrode; and providing a quantum well with at least one quantum dot region formed in the quantum well. The quantum dot region is configured to form a quantum dot upon energization of the at least one gate electrode. The quantum dot is configured to host a spin. Further steps include spacing the chip with the gate stack a predetermined distance from the quantum well, so that the at least one gate electrode is separated from the quantum dot by a strain isolation gap; and inhibiting strain from propagating from the at least one gate electrode into the quantum well, using the strain isolation gap.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 depicts a suspended gate structure in a semiconductor quantum device, according to an illustrative embodiment.

FIG. 2 depicts a flip chip gate structure in a semiconductor quantum device, according to an illustrative embodiment.

FIG. 3 depicts a suspended gate and its anchor(s) in a semiconductor quantum device, according to an illustrative embodiment.

FIG. 4 depicts a suspended plunger gate and two suspended barrier gates, according to an illustrative embodiment.

FIG. 5 through FIG. 12 depict steps of a method for making suspended gates in a semiconductor quantum device, according to an illustrative embodiment.

FIG. 13 through FIG. 20 depict steps of another method for making suspended gates in a semiconductor quantum device, according to an illustrative embodiment.

FIG. 21 depicts a flow diagram of the method that is shown in FIG. 5 through FIG. 12.

FIG. 22 depicts a flow diagram of a method for use of the structure shown in FIG. 2.

FIGS. 23 and 24 depict various aspects of arrays of semiconductor quantum devices, in accordance with aspects of the invention.

FIG. 25 depicts a computing environment according to an embodiment of the present invention (e.g., for implementing a design process such as that of FIG. 26).

FIG. 26 is a flow diagram of a design process used in semiconductor design, manufacture, and/or test.

FIG. 27 is an exemplary cross-section through an anchor portion, in accordance with aspects of the invention.

FIG. 28 through FIG. 37 depict steps of still another method for making suspended gates in a semiconductor quantum device, according to an illustrative embodiment.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of technology described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary semiconductor structure 2101 includes a semiconductor substrate 2108; a gate electrode 2104 separated from the semiconductor substrate by a strain isolation gap; and a quantum dot region 2110 formed in the substrate underneath the gate electrode. The quantum dot region is configured to form a quantum dot upon energization of the gate electrode. The quantum dot is configured to host a spin. Technical benefits of such a structure include quantum dots that are effectively isolated from strain; increased breakdown voltages and/or the overall reduction of dielectrics in the stack (which can be noisy); structures with a gap (for example a vacuum gap) that can separate two materials that do not make a good interface (for example TiN is known to steal oxygen atoms from SiO, thus making the oxide weak)—generally, any type of diffusion can be mitigated with the gap; and/or semiconductor structures that can be used in implementing a quantum computer with improved strain relief and/or noise reduction due to improved interfaces/dielectric thickness.

The semiconductor substrate can include, for example, a “plain vanilla” substrate (bulk), silicon-on-insulator (SOI), compound semiconductor substrate, or semiconductor substrate with a quantum well, for example—other non-limiting examples are set forth herein. Note also that the strain isolation gap can optionally be partially filled with one or more dielectric materials.

Further regarding the quantum dot being configured to host a spin, in principle, the quantum dot is an isolated puddle of a single or a couple of charge carriers under the gate electrode. If it is a single charge carrier, that single charge carrier has the property of spin and it becomes the spin qubit where the information is encoded. For spin half encoding, one spin equals one qubit. There are also encodings where up to three spins make a qubit. Thus, it can be stated that the quantum dot is configured to host a spin—the spin could be all or part of a spin qubit.

In some instances, the gate electrode is a first gate electrode, and the structure further includes a second gate electrode 2102 adjacent to the first gate electrode. The first gate electrode is a plunger gate electrode, and the second gate electrode is a barrier gate electrode that is also separated from the semiconductor substrate by a strain isolation gap (this gap can be the same as, or different than, the gap that separates the gate electrode 2104 from the semiconductor substrate by a strain isolation gap; in the examples shown in the drawings, it is the same gap). In principal, a device could be made where the barrier sits normally on the chip (i.e., the barrier has no gap only the plunger gate has a gap).

Technical benefits include the ability to lower the potential barrier between two neighboring quantum dots and therefore control the exchange coupling between adjacent spins, facilitating, e.g., entanglement.

One or more embodiments further include an anchor 302; the gate electrode is attached to the semiconductor substrate by the anchor. Technical benefits include the ability to readily fabricate structures with a strain isolation gap. In one or more embodiments, it is appropriate to consider thickness of sacrificial oxide (or other sacrificial material) layer that is etched and defines the gap; for example, the oxide layer 1902 can be used to adjust the width of the gap 1702.

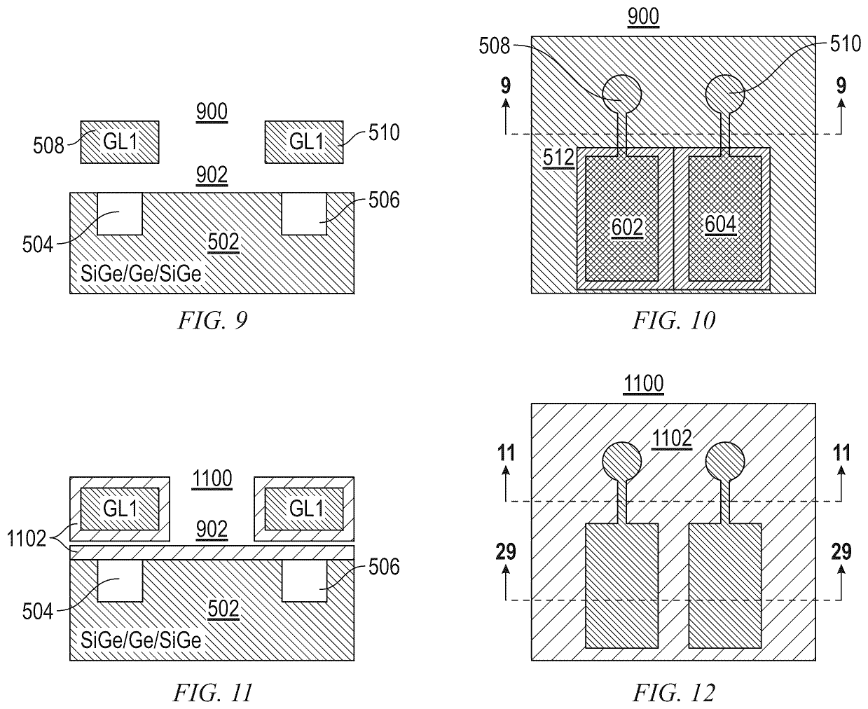

One or more embodiments further include a dielectric layer 512 interposed between the anchor and the semiconductor substrate. The gate electrode is cantilevered from the anchor (see, e.g., FIG. 4) and the dielectric layer has a thickness equal to, and defining, the strain isolation gap. Technical benefits include the ability to readily fabricate structures with a strain isolation gap using lithography. Note, these features are optional and alternatively a similar approach could be used then with additional deposition of a dielectric material using, e.g., atomic layer deposition (ALD), in which case the strain-isolation gap is smaller than the thickness defined here.

In some instances, as seen for example in FIG. 4, the gate electrode has a gate electrode diameter, and the anchor has an anchor width greater than the gate electrode diameter when viewed in plan. Also included is an attachment portion, the gate electrode being attached to the anchor by the attachment portion (narrow portion between anchor and electrode not separately labeled), and the attachment portion is narrower than the gate electrode diameter when viewed in plan. Technical benefits include the ability to readily fabricate structures with a strain isolation gap using lithography, with a stable anchor that does not unduly influence the electrode. Note, these features are optional, and conceptually, there is no reason why the sizes need to compare in this manner—in principle, there is no reason that the anchor cannot be smaller (it may just be harder to fabricate).

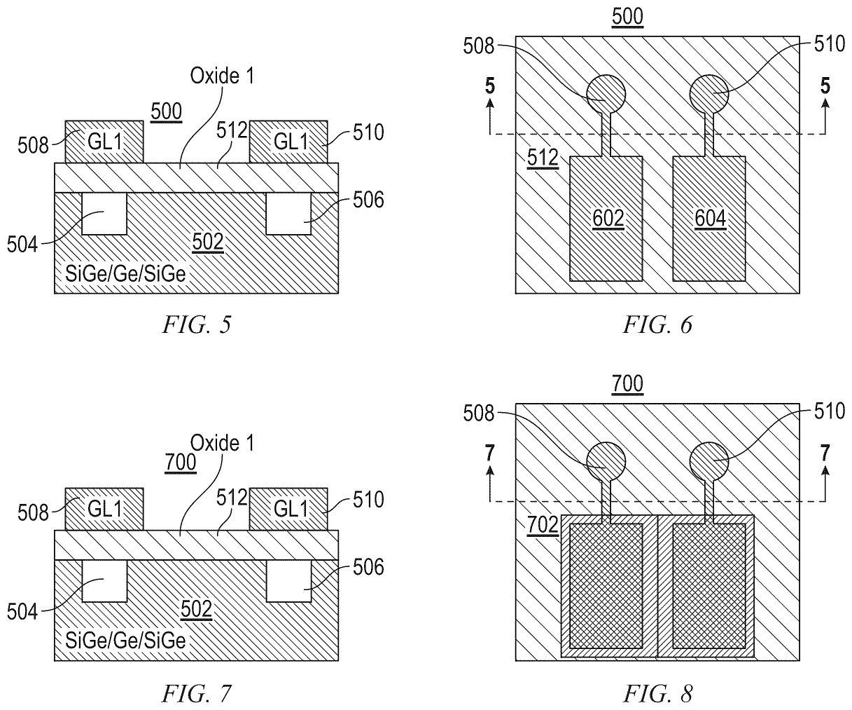

In some instances, such as seen in FIG. 3, the previously-mentioned anchor is a first anchor, and the device further includes a second anchor. The gate electrode is also attached to the semiconductor substrate by the second anchor. Technical benefits include a more stable gap than the cantilevered approach.

One or more embodiments further include a dielectric layer interposed between the first and second anchors and the semiconductor substrate. The gate electrode is suspended between the anchors (see, e.g., FIG. 4) and the dielectric layer has a thickness equal to, and defining, the strain isolation gap. Technical benefits include the ability to readily fabricate stable structures with a strain isolation gap using lithography.

In one or more embodiments, the gate electrode has a gate electrode diameter, the first anchor has a first anchor width greater than the gate electrode diameter when viewed in plan, the second anchor has a second anchor width greater than the gate electrode diameter when viewed in plan (the two anchors optionally have the same width), and the device further includes first and second attachment portions. The gate electrode is respectively attached to the first and second anchors by the first and second attachment portions, and the first and second attachment portions are narrower than the gate electrode diameter when viewed in plan. Technical benefits include the ability to readily fabricate stable structures with a strain isolation gap using lithography, with a stable anchor that does not unduly influence the electrode. Note, these features are optional, and conceptually, there is no reason why the sizes need to compare in this manner—in principle, there is no reason that the anchor cannot be smaller (it may just be harder to fabricate).

In some cases, the substrate includes a germanium-on-insulator structure.

Technical benefits include the ability to fabricate a desirable structure with readily available germanium-on-insulator material.

In some cases, the substrate includes a silicon-on-insulator structure. Technical benefits include the ability to fabricate a desirable structure with readily available silicon-on-insulator material.

In some cases, the substrate includes bulk germanium. Technical benefits include the ability to fabricate a desirable structure with readily available bulk germanium material.

In some cases, the substrate includes bulk silicon. Technical benefits include the ability to fabricate a desirable structure with readily available bulk silicon material.

In some cases, the substrate includes a compound semiconductor heterostructure with a quantum well. Technical benefits include the ability to fabricate a desirable structure in a high quality, low disorder heterostructure.

In one or more embodiments, the semiconductor substrate is pre-accumulated with either electrons or holes. Technical benefits include the ability to provide a desirable structure that operates in depletion mode. Further regarding depletion mode, the depletion mode inverts the functionality of the gates in the sense that the charge is not accumulated under the plunger gate but instead it is pushed away until the single charge carrier remains. Traditional depletion mode quantum dots are “stadium style” as there is an area not covered by a gate with pinching-off around it. The pinch-off also ensures that there is only a single spin in it. In depletion mode, the substrate is already accumulated as a two-dimensional sheet of electrons or holes that is cut into quantum dots with the gates.

It is also worth noting that there are ways to make quantum dots besides a flat semiconductor surface, such as a nanowire or Fin-type Field Effect Transistor (FinFET), which can also benefit from exemplary strain isolation gaps such as those disclosed herein.

At least some embodiments further include a voltage source 2697 coupled to the gate electrode and a controller 2699 coupled to the voltage source. The controller is configured to cause the voltage source to energize the gate electrode to form the quantum dot. Technical benefits include controlling operation of the structure.

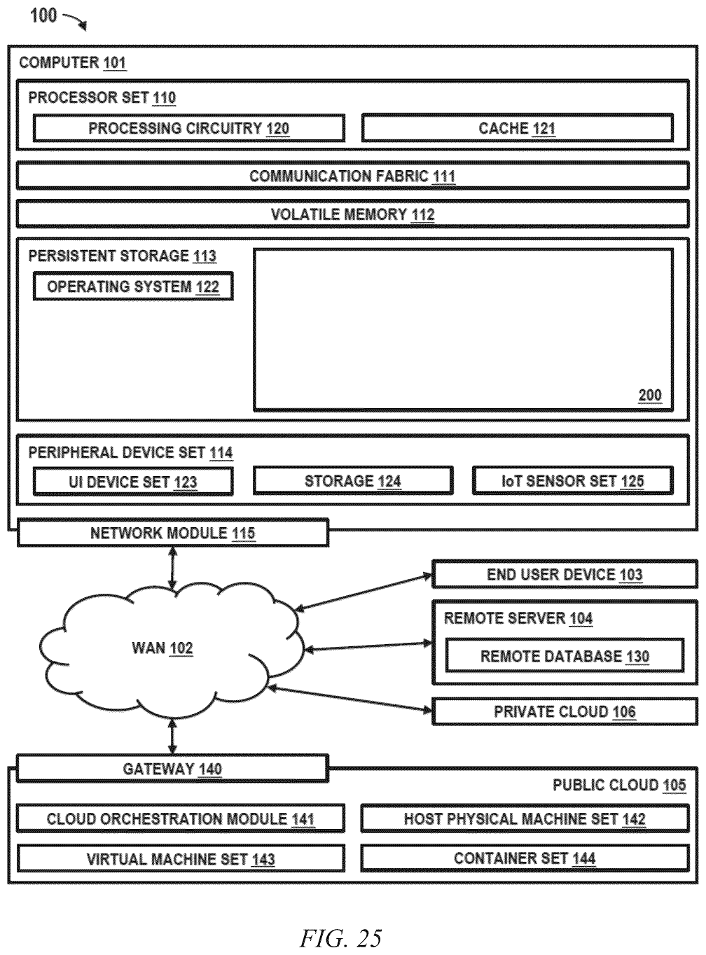

In another aspect, an exemplary quantum processing unit includes an array of quantum semiconductor structures (see FIGS. 23 and 24). Each quantum semiconductor structure includes: a semiconductor substrate 2108; a gate electrode 2104 separated from the semiconductor substrate by a strain isolation gap; and a quantum dot region 2110 formed in the substrate underneath the gate electrode. The quantum dot region is configured to form a quantum dot upon energization of the gate electrode. The quantum dot is configured to host a spin. A voltage source 2697 is coupled to the gate electrode of each quantum semiconductor structure. A controller 2699 is coupled to the voltage source. The controller is configured to cause the voltage source to selectively (e.g., independently) energize the gate electrode of each quantum semiconductor structure. Technical benefits include semiconductor structures that can be used in implementing a quantum computer with improved strain relief, less inhomogeneity across arrays of quantum dots stemming from inhomogeneity in the gate stack, and/or noise reduction due to improved interfaces/dielectric thickness (regarding less inhomogeneity, in some instances, it may be important to have identical quantum dots).

In one or more embodiments, for one or more of the semiconductor structures, the gate electrode is a first gate electrode, and the one or more of the semiconductor structures further include a second gate electrode 2102 adjacent to the first gate electrode. The first gate electrode is a plunger gate electrode, the second gate electrode is a barrier gate electrode, and the second gate electrode also is separated from the semiconductor substrate by a strain isolation gap. Technical benefits include control over the wavefunction overlap and exchange coupling between neighboring spins without introducing a local strain gradient at the edge of the quantum dots.

In one or more embodiments, the semiconductor substrate of each semiconductor structure includes a single common substrate; i.e., the semiconductor structures of the array are formed on a single substrate. Technical benefits include ease in fabrication.

One or more such embodiments further include at least one anchor for each semiconductor structure and a dielectric layer interposed between the anchors and the semiconductor substrate. The gate electrode for each semiconductor structure is attached to the single common substrate by the anchors. The single common substrate includes a compound semiconductor heterostructure with at least one quantum well. The gate electrodes are suspended from the anchors and the dielectric layer has a thickness equal to, and defining, the strain isolation gap. Technical benefits include the ability to readily fabricate structures with a strain isolation gap using lithography.

With regard to the terminology “at least one quantum well,” in this context, skilled persons will typically mean the entire layer of, e.g., Ge when referring to the quantum well. The terminology “a” quantum well could be used if there is a single layer of, e.g., Ge sandwiched between SiGe. However configurations are possible where there are two quantum wells one on top of the other (e.g., SiGe/Ge/SiGe/Ge/SiGe), so “at least one” is used to encompass both possibilities (single layer or one on top of the other).

More generally, one or more embodiments further include at least one anchor 302 for each semiconductor structure, and the gate electrode for each semiconductor structure is attached to the single common substrate by the anchor. Technical benefits include the ability to readily fabricate structures with a strain isolation gap.

In one or more embodiments, the single common substrate is pre-accumulated with either electrons or holes. Technical benefits include the ability to provide a desirable structure that operates in depletion mode.

In some cases, the single common substrate includes a compound semiconductor heterostructure with at least one quantum well. Technical benefits include the ability to fabricate a desirable structure in a high quality, low disorder heterostructure. It is worth noting that the quantum well is quantum mechanically two dimensional. That means the wavefunction in the vertical direction is fixed. So, much more than just a sharper peak, it is actually quantum confined. This, however, is true for all substrates because it is a requirement for forming a quantum dot (dot requires confinement in all directions). Currently, a pertinent advantage of using heterostructures is the low disorder, but in principle a different substrate that can also reach low disorder could be developed in the future. Another technical benefit includes the ability to fabricate a desirable structure on top of a substrate where the quantum dot is enclosed between two epitaxially grown interfaces.

In some cases, the single common substrate includes a silicon-on-insulator structure. Technical benefits include the ability to fabricate a desirable structure with readily available silicon-on-insulator material.

In some cases, the single common substrate includes a germanium-on-insulator structure. Technical benefits include the ability to fabricate a desirable structure with readily available germanium-on-insulator material.

In some cases, the single common substrate includes one of bulk germanium and bulk silicon. Technical benefits include the ability to fabricate a desirable structure with readily available bulk germanium or bulk silicon material.

In another aspect, an exemplary method of providing strain relief in a quantum processing unit includes providing a semiconductor structure (of any of the types described herein) that includes at least one gate electrode separated from a quantum dot region by a strain isolation gap. The quantum dot region is configured to form a quantum dot upon energization of the gate electrode, and the quantum dot is configured to host a spin. A further step includes; and in step 2308, inhibiting strain from propagating from the at least one gate electrode into the quantum well, using the strain isolation gap. Technical benefits of include the ability to provide strain relief.

One or more embodiments further include forming the semiconductor structure by: in step 2302, providing a chip with the gate stack including the at least one gate electrode; in step 2304, providing a quantum well with the quantum dot region formed therein (the quantum dot region is configured to form a quantum dot upon energization of the at least one gate electrode, and the quantum dot is configured to host a spin); in step 2306, and spacing the chip with the gate stack a predetermined distance from the quantum well, so that the at least one gate electrode is separated from the quantum dot by a strain isolation gap. Technical benefits of include the ability to provide strain relief using a flip chip gate structure.

Optionally, the semiconductor structure could be formed using other techniques disclosed herein.

Techniques as disclosed herein can provide substantial beneficial technical effects. Some embodiments may not have these potential advantages and these potential advantages are not necessarily required of all embodiments. By way of example only and without limitation, one or more embodiments can provide one or more of:
quantum dots that are effectively isolated from local strain (by way of a non-limiting example, strain in a cryogenic device, which can be separated into two components: the intrinsic strain from material deposition and the strain that comes from cooling materials that then shrink differently with temperature due to differing coefficients of thermal expansion);
increased breakdown voltages and/or the overall reduction of dielectrics in the stack (which can be noisy);
the gap (for example a vacuum gap) can separate two materials that do not make a good interface (for example TiN is known to steal oxygen atoms from SiO, thus making the oxide weak)—generally, any type of diffusion can be mitigated with the gap;
techniques that can be employed with cryogenic devices (e.g., devices for classical cryogenic computing), since strain can appear, for example, from different thermal expansion coefficients of different materials in a material stack, and such effects can be worse at extreme temperatures, such as cryogenic temperatures;
semiconductor structures that can be used in implementing a quantum computer with improved strain relief and/or noise reduction due to improved interfaces/dielectric thickness.

In operation of a spin qubit quantum computer (e.g., the so-called “spin-1/2 encoding” where a single spin per quantum dot corresponds to a qubit each), a few or single charges get accumulated in the quantum dots, to form the qubit states. In accumulation mode devices, the number of trapped charges per quantum dot is controlled by plunger gates. Entanglement between qubits is then achieved by engineering an overlap between the wavefunctions of neighboring qubits. This can be controlled using barrier gates located in between the plunger gates. An external magnetic field is used to break the energy degeneracy between different spin directions, usually defining the qubit frequency through the g-factor and the principal axis for the spin-qubit. In the so-called “spin-1/2 encoding,” where one spin corresponds to one qubit, a spin in parallel to that principal axis corresponds to the qubit being in the “up” state while a spin anti-parallel to the principal axis represents the “down” state of the qubit. There are multiple choices for “encoding” spin qubits. The simplest one is where a single spin of a single electron/hole forms the qubit (spin is pointing up or down and those are the qubit states). However, it is also possible to encode spin-qubits in 2 or 3 quantum dots. The terminology “to form the qubit states” is intended to be inclusive in this way. Further regarding the plunger gates, the notation “in accumulation-mode devices” refers to the fact that in some materials, there are no plunger gates because the material is already accumulated even without gating. In that case the gates deplete the material and isolate a circular (but can also be, for example, cigar-shaped) accumulated region that forms the quantum dot.

A plunger gate includes a metallic electrode placed near a quantum dot or set of quantum dots. Plunger gates can be fabricated using standard semiconductor manufacturing techniques. By applying an electric voltage to a plunger gate, the electric field in the vicinity of the underlying quantum dot is altered, thereby affecting the energy levels of the electrons confined within. This manipulation of energy levels enables control of the quantum state of the electrons.

Plunger gates are used in various quantum computing applications. For example, a plunger gate may be used to tune the occupation numbers of the quantum dot. Within the plunger voltage window that corresponds to a given occupation number, the plunger gate may also be used to adjust the energy of an electron/hole state. When compared to the electron/hole state in a neighboring quantum dot this constitutes an energy detuning between adjacent qubits than can be used to control the exchange interaction and perform operations on the qubits. Additionally, changes in plunger gate voltages, in some cases, can alter the qubit frequency in a spin-½ encoding.

Barrier gates are typically used to control the quantum tunnel barriers by locally engineering the wavefunction overlap between the wavefunctions of neighboring qubits.

A quantum dot's bit value may be set by a magnetic field, to which the spin of the given quantum dot may be parallel or anti-parallel; the two options have different energy levels for a two-level or bitwise quantum system. In conventional spin qubit quantum dots, a solid interface between gate material and quantum dot material can introduce thermal strain due to differing coefficients of thermal expansion between the gate and the quantum dot. This thermal strain can impact both the qubit frequency (energy difference between up and down, “Lamor frequency”) as well as the driving speed (how quickly a certain pulse can turn the spin from up to down, “Rabi-frequency”). Technically there can also be small changes to the orientation of the “principal qubit axis.” These phenomena detract from efficient operation of the quantum computer.

We have found that the problems associated with a solid gate-to-dot interface can be mitigated by introducing a strain isolation gap between the gate and the dot. As used herein, a “strain isolation gap” has a vacuum or may contain air or other gas(es). For example, the isolation gap can typically be sealed off in the fabrication, and since all deposition steps of material (including the step that seals the gap) are typically done in vacuum, there would be a relatively good vacuum (e.g., 10⁻⁶ mTorr or better vacuum—pressure no greater than 10⁻⁶ mTorr) in the gap. In an alternative embodiment, the gap is not sealed during fabrication (an opening is left to ambient), and then it becomes evacuated in the cryostat when the device is running. The gap could also be deliberately filled with one or more gases during fabrication and then sealed off.

A pertinent feature of the gap is that it does not have a solid structure. Thus, the dot is isolated from strain or force of the gate.

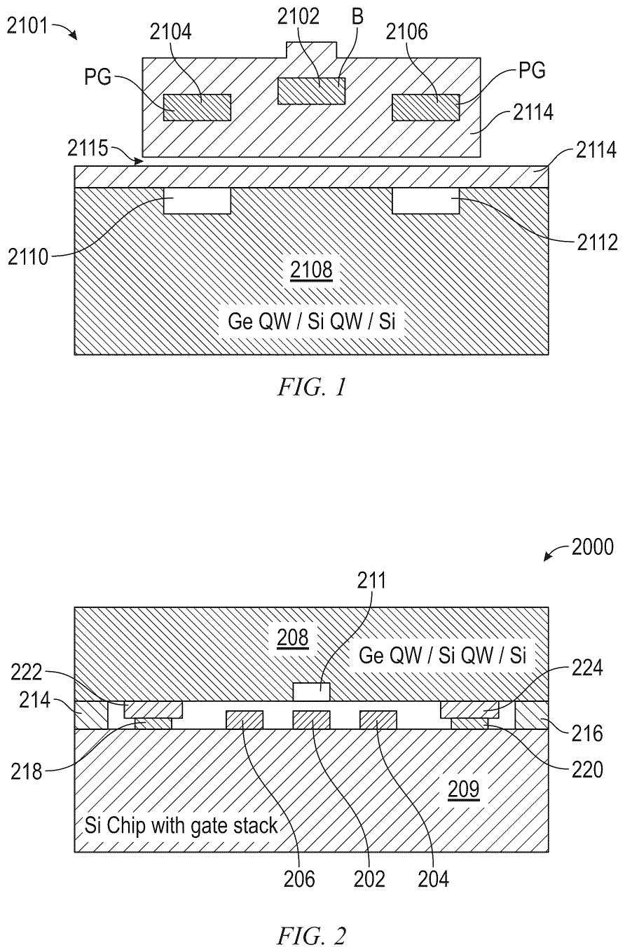

Accordingly, FIG. 1 depicts a suspended gate structure 2101 in a semiconductor quantum device, according to an illustrative embodiment. The suspended gate structure 2101 includes a barrier gate 2102 and two plunger gates 2104, 2106 above a quantum well 2108 that embodies two quantum dots 2110, 2112. The plunger gates 2104, 2106 are respectively disposed in registry with the quantum dots 2110, 2112; that is, the plunger gates are (inherently) aligned on centers to the quantum dots that are established by energizing the gates. Note the sacrificial oxide 2114 (or other sacrificial material) and strain isolation gap 2115. It is worth noting that dopants are typically a source of noise and/or disorder and one or more embodiments thus employ intrinsic, undoped semiconductor materials in the substrate (an exception could be a contact to the substrate). The substrate can include non-planar features such as fins or nanowires.

In one or more embodiments, the size and alignment accuracy are closely tied to which semiconductor is used, as well as to the type of charge carrier, because there is dependency on the wavelength of the charge carrier in the material. In germanium heterostructures, for example, a typical plunger gate is 100-125 nm wide and the barrier is a bit smaller (for example, on the order of 50-70 nm). The gap in between would typically have to be relatively small, around 10-15 nm, if all gates are written in the same step. The alignment can be more relaxed if written in the same layer, as the distance between gates is not affected by alignment. For fabrication in multiple layers, there are plenty of overlapping gates or self-alignment techniques that can relax the alignment accuracy requirement (those can employ multiple gate fabrication steps and an isolation dielectric). Then, the alignment requirement is on the order of half of a gate width (e.g., 25 nm in the example). It is pertinent to note that advantageously, in one or more embodiments, the alignment and size requirements are not really impacted by the isolation gap and would be very similar if there was just a normal dielectric instead.

In operation of the suspended gate structure 2101, the barrier gate 2102 isolates the quantum dots 2110, 2112. The plunger gates induce charge, and with that, they can induce spin. The spin is only induced if there is an unpaired spin in the system, so in the easiest case (no valley degeneracy), spin would be induced for the first charge carrier, but then it would be paired with an opposite spin for the second charge carrier, effectively “deleting” the spin. For higher occupation numbers, this can become more complicated. Furthermore in this regard, in one or more embodiments, the plunger gates accumulate single, or a few, charge carriers in a quantum dot. Depending on the level structure of the quantum dot, this can then mean that a spin is induced. Measurement of the spin happens indirectly using “spin-to-charge conversion.” This encompasses multiple processes. One is when charge carriers can/cannot travel to a neighboring quantum dot or lead depending on the spin state. In this aspect, measure the charge occupation with, e.g., a nearby sensor, so the plunger gate of the qubit is only indirectly involved, because it needs to tune the underlying quantum dot in a regime where this spin-to-charge conversion can happen. In one or more embodiments, however, the actual sensing is done on the charge sensor. In essence, the plungers are facilitating spin-to-charge conversion.

Another aspect happens directly on the gate. Here, the information about the spin-state is contained in a radio frequency (RF) signal that is reflected off the gate. However, this technique requires another qubit nearby and can only make a statement about whether the spins in those qubits are parallel or antiparallel. It is thus not strictly speaking correct to state that each plunger reads-out the spin below. Instead, the information from a single plunger gate can typically only give the spin state if more information about the neighboring spins is available. For example, if it is known that the neighboring spin is up and the read-out on the plunger indicates that the spin underneath has the same orientation as that neighboring spin, then it is known that the spin under the plunger is also up.

Thus, to summarize, the plunger gates can be used to measure information about the spin, but not immediately the spin state, without information from elsewhere. This is known as parity read-out (parity referring to whether spins are parallel or antiparallel).

A quantum well is, for example, a heterostructure of thin layers of different semiconductors with different band gaps. A quantum well is usually a sandwich, such as, for example, SiGe/Si/SiGe, where the electrons then get trapped in the Si layer. There are in practice more layers underneath (typically SiGe layers with decreasing Ge content to have a slow transition to a silicon substrate that the quantum well is grown on), to make sure the sandwich structure is mechanically stable. Thus, semiconductors such as silicon or germanium may be used. In some implementations, a high quality oxide could be used. When the layer thickness approaches the de Broglie wavelength of electrons at a given temperature, it is possible to energize the quantum well so that the electrons can be trapped in discrete quantum states. A quantum dot is a semiconductor crystal a few nanometers in size, approaching the Fermi wavelength of the electrons in the semiconductor, which is bounded by either material interfaces to an insulator or a semiconductor material in depletion. Quantum dots sometimes are referred to as artificial atoms, because electrons trapped in quantum dots show similar energy spectra and the shell filling is governed by similar selection rules as for electrons bound to atomic nuclei. One type of quantum dot, which can be used to form spin qubits, is the lateral quantum dot, which is formed by depositing or etching a lateral electrode pattern at the surface of a quantum well. The electrode pattern can be used to tune the underlying quantum well such that one or multiple quantum dots are bounded by depleted semiconductor material on all sides. Another type of quantum dot is an ultra-small (in a non-limiting example, 20 nm×20 nm) complementary metal oxide semiconductor (CMOS) transistor (depending on whether electrons or holes), which can behave as a single electron quantum dot when operated at cryogenic temperature sufficiently cool to operate a spin qubit. In this aspect, electrodes can locally accumulate quantum dots when the electron/hole is pressed against the semiconductor-to-oxide interface and the device is operated at cryogenic temperature sufficiently cool to operate a spin qubit. The temperature range can be, for example, from absolute zero (0 K) up to about 15 K, or from absolute zero (0 K) up to 4.2 K (temperature of liquid Helium). For example, a dilution refrigerator can achieve a temperature of about 10 mK.

Optionally, an oxide layer 2114 may be deposited around the gates and onto the quantum well, e.g., in order to control the width of the gap between the gates and the dots.

Since a gate cannot just “float” apart from the quantum well, in one or more embodiments, some form of anchor is provided for a suspended gate. For example, FIG. 3 depicts a suspended gate 300 and its anchor(s) 302, 304 in a semiconductor quantum device, according to an illustrative embodiment. Anchor 304 is optional, and additional anchors may be provided in other embodiments. The anchor(s) are attached to an underlying semiconductor structure. For example, in the case of a heterostructure, the quantum well is the part where the charge carriers are trapped (e.g. the Si in SiGe/Si/SiGe). The anchor is thus attached to the SiGe or to some oxide on top of the SiGe (this can be visualized as attaching the anchor(s) to the “bread” part of a sandwich, with the quantum well located in the sandwich filling not the bread). Either or both of anchors 302 and/or 304 may be mounted on a screening gate (not shown). The exact geometry of the anchors will depend on many aspects and will have to be developed for every architecture; given the teachings herein, the skilled artisan can size and configure anchors suitable for a given application.

A quantum logic gate is an operation that is placed on a quantum processor as a part of an algorithm to be run. The classical equivalent is the logic gates (such as OR, AND etc.). The screening gate, on the other hand, is a physical piece of metal. It is used to screen the electric field from gates above in such a way that the semiconductor only sees a small “pointlike” piece of the field, and consequently, a quantum dot is accumulated. Thus, in one or more embodiments, the screening gates are provided to help accumulate a quantum dot in the first place. One non-limiting example is having two rectangular screening gates with a small gap in between. In a higher gate layer, there is a plunger gate (a line) perpendicular to the gap. This results in only a “pointlike” field being applied to the semiconductor, and therefore the accumulation in a quantum dot (accumulation only in one point, not along the entire plunger gate).

The entangling of qubits is usually done by controlling the wavefunction overlap between neighboring quantum dots—a quantum computer typically requires not a single qubit, but rather multiple entangled qubits. Indeed, a single isolated gate is typically not very useful for making an operational quantum circuit. For example, it may be desirable to have both a plunger gate for establishing a quantum state in a quantum dot, as well as one or more barrier gates to contain the quantum state. Accordingly, FIG. 4 depicts a suspended plunger gate 402 and two suspended barrier gates 404, 406, according to an illustrative embodiment. Each of the gates 402, 404, 406 has a respective anchor 408, 410, 412. The anchors 408, 410, 412 are attached to an underlying substrate/semiconductor structure (refer to “sandwich” example above). Note, while it is true that the barriers also help restricting the quantum dots (=shape the confinement potential), another pertinent function is to control the overlap. It is worth noting that this is quite different from classical transistor logic, where transistors can in principle be far away from each other as long as there is some sort of routing in-between. Thus, the barrier gates, on the one hand, function to shape the confinement potential of the qubit, but on the other hand, also function to engineer the wave function overlap—this creates entanglement which is one aspect that unlocks the power of quantum computing.

Individual devices can be arranged in an array according to one or more embodiments. FIG. 23 shows a cross section of such an array; note the substrate 2401, oxide 2403 (or other material) with gap 2409, plunger gates 2405, and barrier gates 2407. In the non-limiting example, the substrate is SiGe/Ge/SiGe, but other materials can be used as noted herein. The ellipses indicate that the array can continue.

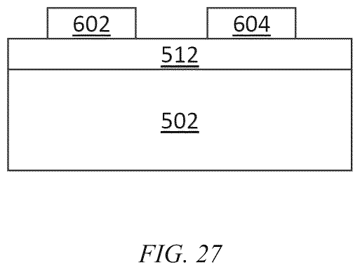

FIG. 24 shows an exemplary top view of an accumulation mode array. Note the plunger gates P, barrier gates B, and non-limiting example of potential places for anchors 2441, it being understood that the anchor locations are purely a non-limiting example and that other embodiments could have other locations. To avoid clutter, only the rightmost three exemplary anchor locations are numbered. Note the controller 2699 and voltage source 2697 coupled to one or more of the gates. The voltage source energizes the gate(s) under control of the controller to cause the quantum dot(s) to be instantiated in the quantum dot region(s). The voltage source can include a DC voltage to form the quantum dot(s) as well as RF to operate the qubits; thus, in a non-limiting example, the voltage source has both DC, and AC in the RF (radio frequency) and MW (microwave) domains. The skilled artisan will be familiar with coupling, entanglement, read-out, and interconnection to external devices/ports. The controller 2699 carries out functions as will be apparent to the skilled artisan; given the teachings and description herein, known control circuit technologies can be employed—e.g., multicycle or pipelined, hardwired or microprogrammed, using any suitable technology family (e.g., 7 nm CMOS, 5 NM CMOS, and the like). For example, the specified functions can be instantiated in logic circuitry as described below with respect to FIG. 26. The elements in FIG. 24 can be enclosed in a cryogenic refrigerator 2695.

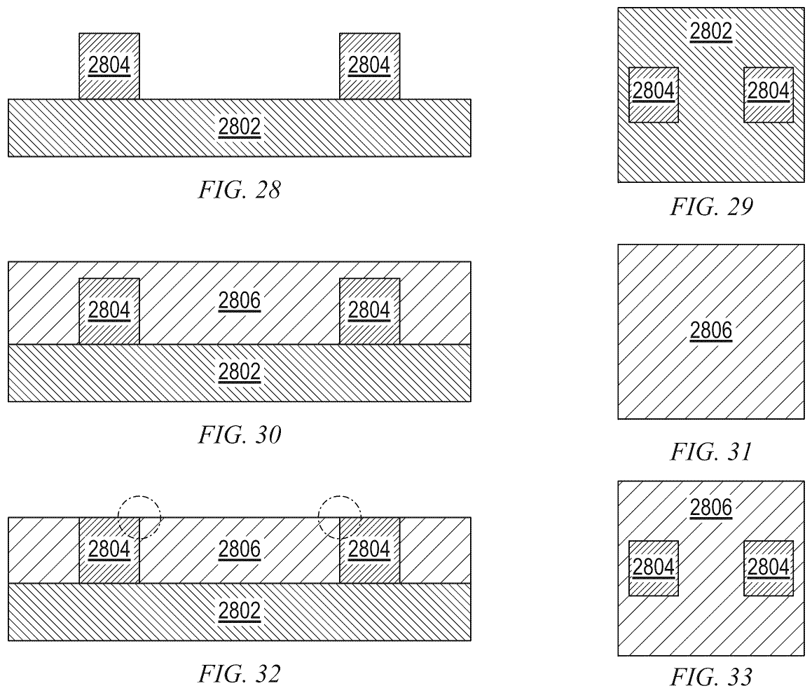

FIG. 27 is a cross-section through the anchors along line 29-29 in FIG. 12, Note the substrate/quantum well 502, sacrificial layer 512 that has not been etched away under the anchors, and the anchors 602, 604. A portion of FIG. 27 with a single one of the anchors is also generally representative of views along the section lines A-A in FIG. 3 and B-B in FIG. 4 (and would be similarly representative of sections through the anchors 410, 412).

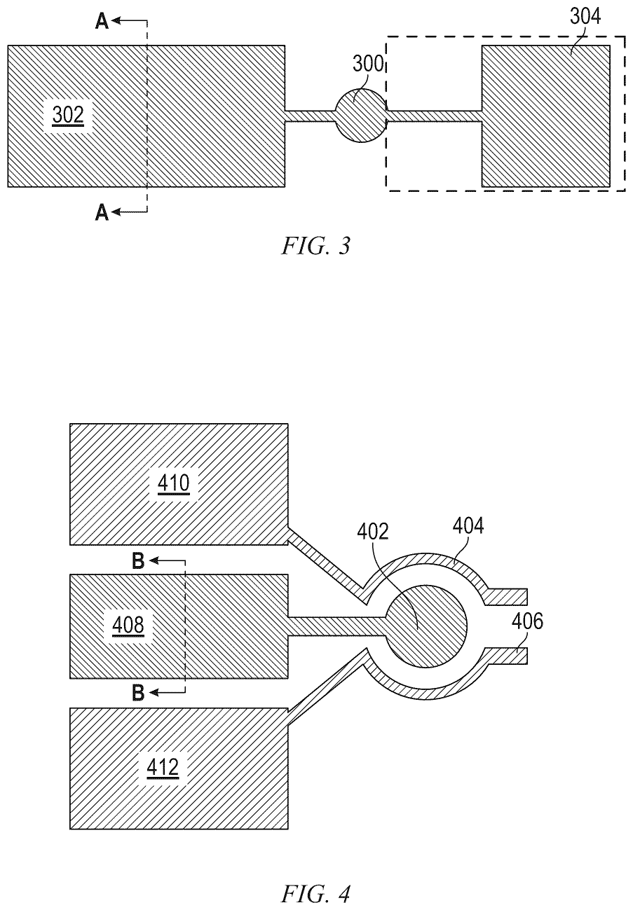

As an alternative to the suspended gate structure shown in FIG. 1, FIG. 2 depicts a flip chip gate structure 2000 in a semiconductor quantum device, according to an illustrative embodiment. The flip chip gate structure 2000 includes a plunger gate 202 and two barrier gates 204, 206 below a top chip with quantum well 208 that embodies a quantum dot 211. By way of clarification, the quantum well is a part of the substrate that contains the qubit; it can be associated to a specific layer in a heterostructure (the inside of the “sandwich”) or a triangular quantum well on the interface of a bulk semiconductor that is induced by the gate electrode pulling electrons or holes towards the interface. In both cases, the quantum well is just a small part of the overall substrate. Element 208 can thus be referred to as a top chip/substrate that contains the quantum well where the quantum dot is located.

Now continuing, the plunger gate 202 is (inherently) disposed in registry with the quantum dot 211. In operation of the flip chip gate structure 2000, the barrier gates 204, 206 isolate the quantum dot 211 (the barrier gates are next to the contacts to regulate the tunneling from the contact into the quantum dot). The flip chip gate structure 2000 also includes spacer pillars 214, 216 that hold a top chip with quantum well 208 above the gates. The flip chip gate structure 2000 further includes routing pads 218, 220, as well as ohmic contacts 222, 224 that bond the routing pads to the quantum well. FIG. 2 thus depicts a portion of an array with a contact on each side; next to each contact, there is a barrier. This permits control of access to the contact. Generally, the order is contact—barrier—qubit; then, one qubit or an array of qubits; then on the other side again qubit—barrier—contact.

Further regarding the routing pads 218, 220 and ohmic contacts 222, 224, routing, as used herein refers to signal routing, which can be accomplished, in one or more embodiments, similar to how it would be done in any classical processor. Basically, it is desired to get a signal from the outside world into a specific spot in the architecture, and that can typically require a complicated network of lines that deal with bringing signals to the right spot in a device with a very high density of lines (typically requiring many layers in the back end of line (BEOL)). There are also multiplexing strategies that can be employed in a typical case, because that reduces the overall number of lines that connect to the outside world. Given the teachings herein, the skilled artisan can adapt known BEOL wiring techniques, using, for example, horizontal metal layers and vertical vias, to route signals in one or more embodiments.

A pertinent aspect in one or more embodiments is the ohmic contact to the quantum well. This is used for loading electrons/holes into the quantum dots and can also be used for read-out and initialization. Depending on the architecture, those ohmic contacts might be employed frequently in a 1-D or 2-D gate-array (not just on the edges of the array). That implies that the ohmic contacts are at multiple points in the center of a gate array and one or more appropriate connections can be employed to get signals into the package, using appropriate routing.

To route a signal from e.g. a voltage source outside of the flip chip package into the quantum well on the top substrate, it is possible to make the bottom chip 209 larger than the top chip 208 and make a connection to the bottom chip away from the top chip. On the bottom chip, this signal can then be routed under the top chip and into the top chip through inter-chip connections. Alternatively, the top chip can be contacted from above and the signal can be routed to the bottom side of the top chip using through-silicon-vias.

### Aspects of Fabrication

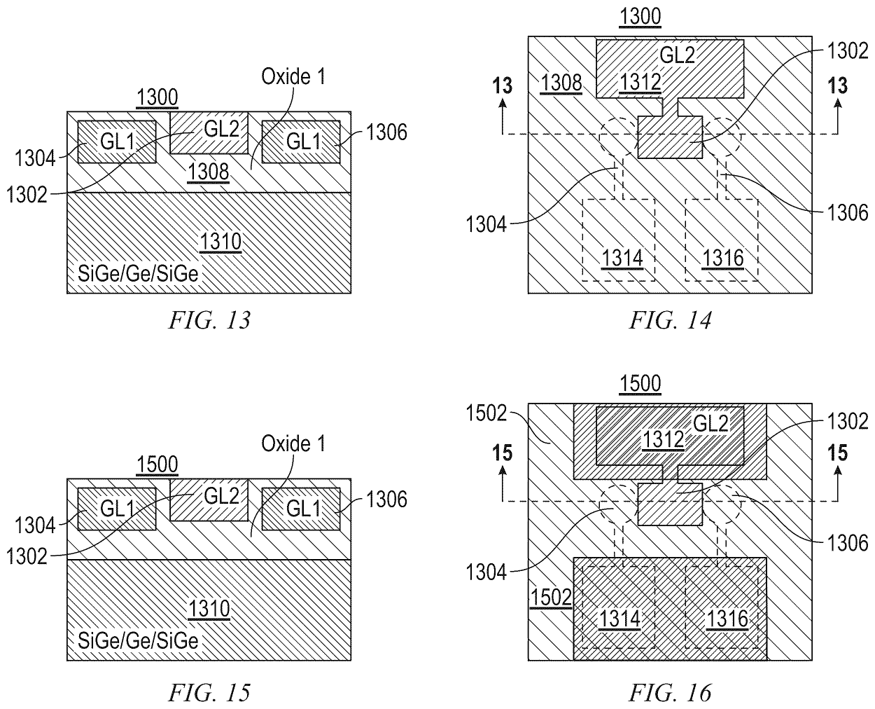

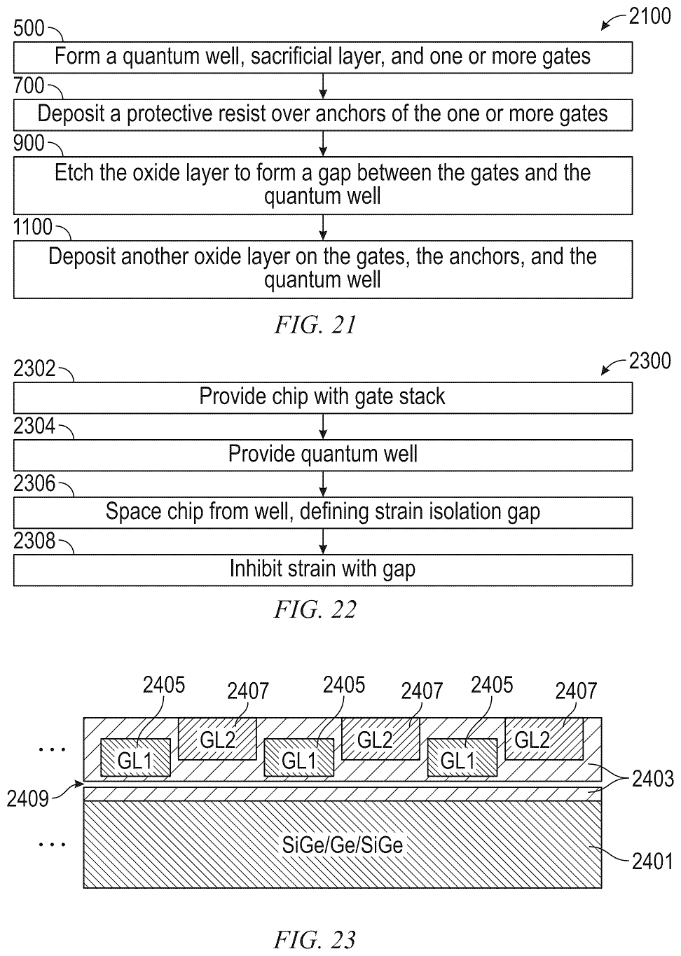

Various techniques may be used to fabricate a suspended gate structure. For example, FIG. 5 through FIG. 12 depict steps 500, 700, 900, 1100 of a method 2100 (which is shown in a flow diagram in FIG. 21) for making suspended gates in a semiconductor quantum device, according to an illustrative embodiment.

At 500, form a quantum well 502, sacrificial layer, and one or more gates 508, 510. In one or more embodiments, this sacrificial layer can be selectively etched against the gates 508, 510 and the substrate/quantum well 502. The sacrificial layer can be an oxide layer such as oxide layer 512 but other materials besides an oxide can be used. In operation, the gates will form quantum dots 504, 506 by accumulating a small section of the semiconductor (analogously to the gate in a field effect transistor creating a channel when energized). In one or more embodiments, there is no separate step to “form” the quantum dots other than energizing the gates during operation. In operation, the one or more gates 508, 510 will inherently be in registry with respective ones of the quantum dots 504, 506. It is worth noting as an aside that there are also implementations where the semiconductor is accumulated by default and the gates pinch off a small section (every gate is a barrier then). Now continuing, in one or more embodiments, the gates 508, 510 are a metallic material (either a metal or doped polycrystalline semiconductor) formed on a dielectric layer 512. The dielectric layer ensures that there is no current from the gate to the semiconductor below. As noted, the dielectric layer can be, for example, an oxide, but is not necessarily an oxide (nitrides work too, for example). In some cases, the oxide layer 512 can be aluminum oxide or silicon oxide; the oxide layer 512 should etch selectively against the gate material and the semiconductor (or whatever layer is on top of it) to ensure that the entire structure is not etched away when the gates are suspended. One or more embodiments thus also include a sacrificial layer that enables suspending the gates. FIG. 5 shows an end view of step 500, taken at view line 5 in FIG. 6, while FIG. 6 shows a plan view of step 500 including anchors 602, 604.

The quantum dots 504, 506 are depicted in subsequent steps for illustrative clarity, it being understood, as discussed above, that they only form during operation.

With regard to step 500, it should be understood that, as discussed elsewhere herein, there are also implementations where the semiconductor is accumulated by default and the gates pinch off a small section (every gate is a barrier then).

At 700, deposit a protective resist 702 over anchors 602, 604 (seen in FIG. 6) of the gates 508, 510. FIG. 7 shows an end view of step 700, taken at view line 7 in FIG. 8, while FIG. 8 shows a plan view of step 700. The resist is optional; it is possible to form both the anchors and the suspended gates by simply making the anchors much larger than the gates, so that not all of the oxide under the anchors gets etched by the time that the oxide under the gates has been fully etched to separate the gates from the quantum well.

At 900, etch the oxide layer 512 (seen in FIGS. 5 and 7) to form the gap 902 between the gates and the quantum well. For example, a wet etch may be used. The protective resist 702 (seen in FIG. 8) prevents etching of the oxide 512 around the anchors 602, 604. Then remove the resist. FIG. 9 shows an end view of step 900, taken at view line 9 in FIG. 10, while FIG. 10 shows a plan view of step 900. The gates 508, 510 are left suspended above the quantum well 502.

At 1100, deposit an oxide layer 1102 on the gates 508, 510 (numbered in FIGS. 9 and 10), the anchors 602, 604 (seen in FIG. 10), and the quantum well 502. The oxide layer 1102 may be the same or different oxide as the oxide layer 512 in FIG. 10; there is no particular requirement as to the chemistry of the oxide layer 1102. The oxide layer 1102 may be used to adjust the width of the gap 902. Step 1100 is optional. FIG. 11 shows an end view of step 1100, taken at view line 11 in FIG. 12, while FIG. 12 shows a plan view of step 1100. Note that, depending on the materials, it may also be possible to oxidize the structure itself instead of (or in addition to) depositing an oxide. For example, in a metal oxide semiconductor (MOS) with polysilicon (poly-Si) gates, it is also possible to carry out a thermal oxidation which would grow a high quality oxide on the semiconductor and the gates (better than native oxide).

FIG. 21 depicts a flow diagram of the method 2100 that is shown in FIG. 5 through FIG. 12.

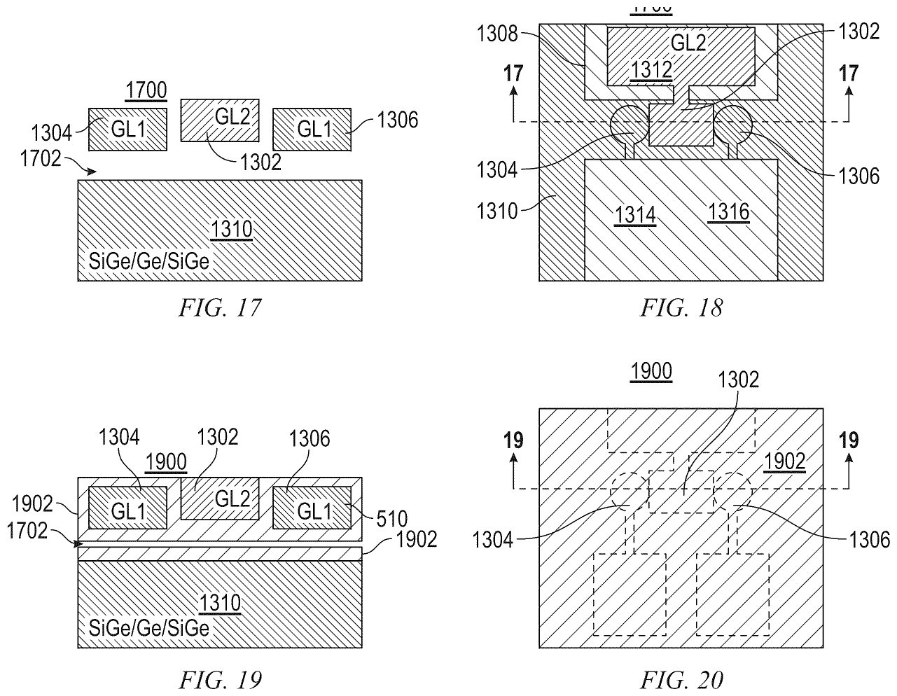

FIG. 13 through FIG. 20 depict steps 1300, 1500, 1700, 1900 of another method for making suspended gates in a semiconductor quantum device, according to another illustrative embodiment. According to the method of FIG. 13 through FIG. 20, a plurality of gates 1302, 1304, 1306 are formed on an oxide 1308 (the oxide is a non-limiting example of a sacrificial layer that can be selectively etched against the gates and the substrate/quantum well 1310 and materials other than oxide can be used) on a plurality of layers above a quantum well 1310 (e.g., with a barrier gate 1302 above two plunger gates 1304, 1306) before forming a vacuum gap 1702 between the gates and the quantum well (see discussion of FIG. 17, below).

Thus, at 1300, form the quantum well 1310, the oxide 1308 (or other material), and the gates 1302, 1304, 1306. For example, the oxide 1308 may be aluminum oxide or silicon oxide; the oxide 1308 should etch selectively against the gate material. FIG. 13 shows an end view of step 1300, taken at view line 13 in FIG. 14, while FIG. 14 shows a plan view of step 1300. Note anchors 1312, 1314, 1316.

At 1500, deposit a protective resist 1502 above anchors 1312, 1314, 1316 of the gates 1302, 1304, 1306. FIG. 15 shows an end view of step 1500, taken at view line 15 in FIG. 16, while FIG. 16 shows a plan view of step 1500. The resist is optional; it is possible to form both the anchors and the suspended gates by simply making the anchors much larger than the gates, so that not all of the oxide under the anchors gets etched by the time that the oxide under the gates has been fully etched to separate the gates from the quantum well.

At 1700, etch the oxide 1308 to form the gap 1702 between the gates and the quantum well. For example, a wet etch may be used. The protective resist 1502 (as seen in FIG. 16) prevents etching of the oxide 1308 around the anchors 1312, 1314, 1316. Then, remove the resist. FIG. 17 shows an end view of step 1700, taken at view line 17 in FIG. 18, while FIG. 18 shows a plan view of step 1700. In FIG. 17, for clarity, the gap 1702 is shown without the wall that is formed by the oxide 1308 around the anchor 1312, and similarly in FIG. 19, which is further described below.

At 1900, deposit an oxide layer 1902. The oxide layer 1902 may be the same or different oxide as the oxide 1308; there is no particular requirement as to the chemistry of the oxide layer 1902. The oxide layer 1902 can be used to adjust the width of the gap 1702. Step 1900 is optional. FIG. 19 shows an end view of step 1900, taken at view line 19 in FIG. 20, while FIG. 20 shows a plan view of step 1900. Note that in one or more embodiments, the oxide 1902 is deposited conformally on every surface. This includes the substrate and the gates.

The method depicted in FIG. 13 through FIG. 20 thus provides for two or more gate layers than can be fabricated even with an overlap if desired (the gate layers then should be separated by the same material that is used as the sacrificial layer). The flow is then: first, form QW, sacrificial layer and first gate layer; next, form (another) sacrificial layer from the same material as the first sacrificial layer; then, form another gate layer (repeating until the desired number of gate layers is reached). Finally, etch the sacrificial layer selectively and deposit another oxide layer to “tune” the gap size. FIGS. 13 and 14 thus show the result of several rounds of making gate layers; FIGS. 17 and 18 show the selective etching; and FIGS. 19 and 20 show the “tuning” of the gap size.

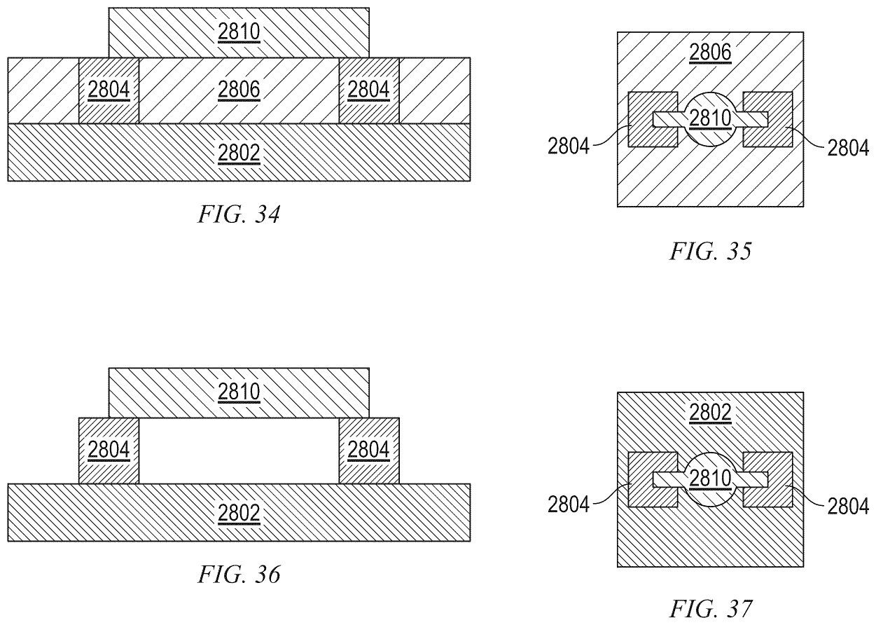

FIG. 28 through FIG. 37 depict steps of still another method for making suspended gates in a semiconductor quantum device, according to an illustrative embodiment. FIGS. 28, 30, 32, 34, and 36 are side cross-sectional views while FIGS. 29, 31, 33, 35, and 37 are corresponding top views. In FIGS. 28 and 29, form pillars (of a material that is not etched when etching the sacrificial material, e.g., SiO₂) 2804 on the semiconductor substrate 2802; for example, by etching. Other materials could be used. In FIGS. 30 and 31, deposit the sacrificial layer (e.g., AlO) 2806 and in FIGS. 32 and 33, planarize same using chemical-mechanical polishing (CMP) or the like. The gates can then be attached at the encircled corners of the pillars. In FIGS. 34 and 35, fabricate the gates 2810. In FIGS. 36 and 37, under etch material 2806 to create the gap.

Thus, in this aspect, method steps include providing a quantum well (“quantum well” is used as a shorthand in this context; by way of clarification, as noted above, the quantum well is a part of the substrate that contains the qubit); fabricating anchors from a dielectric; depositing a sacrificial layer and planarizing same such that anchors are exposed at the surface of the planarized chip. Further steps include fabricating gates and etching the sacrificial layer (here, no protective resist is required as the gates are already attached to the anchors). This method can also be extended to multiple overlapping gate layers. For example, it is possible to use the sacrificial layer between the gates and then use a protective resist again, and so on.

The “flip chip” structure of FIG. 2 may be formed by a method that includes at least the following steps: (1) provide gate structures, spacers, and routing pads on a first chip; (2) attach a second substrate that contains a quantum well to the first chip, such that the spacers hold the quantum well out-of-contact from the gate structures, i.e. there is a vacuum gap between each gate and a corresponding region of the quantum well.

### Aspects of Operation

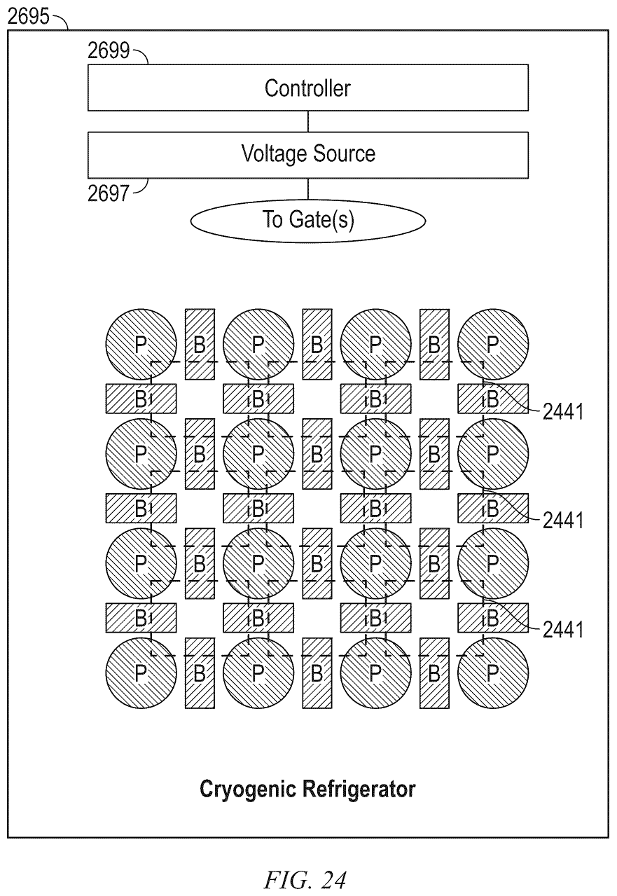

In operation, the “flip chip” structure of FIG. 2 may be used according to steps of a method 2300, as shown in FIG. 22. At 2302, provide a chip with a gate stack having at least one gate electrode. At 2304, provide a quantum well with at least one quantum dot region formed therein. The quantum dot region is configured to form a quantum dot upon energization of the at least one gate electrode, and the quantum dot is configured to host a spin. At 2306, space the chip with the gate stack a predetermined distance from the quantum well (rigid spacers 214, 216 are a non-limiting example), so that the at least one gate electrode is separated from the quantum dot by a strain isolation gap. At 2308, inhibit strain from propagating from the at least one gate electrode into the quantum well, using the strain isolation gap. Rigid spacers 214, 216 are a non-limiting example for spacing the chip from the well.

It will be appreciated that, sometimes when metal is deposited on a substrate, the metal is significantly hotter than the substrate, and when cooling to ambient temperature, there is already an inherent strain that the gate electrode has on the semiconductor substrate.

Also, when cooling down to cryogenic temperatures, thermal strain will be induced because the semiconductor substrate, the metal, and the in-between dielectric have different coefficients of thermal expansion.

### Additional Comments

It is worth reiterating that in operation, the gates will form quantum dots by accumulating a small section of the semiconductor (analogously to the gate in a field effect transistor creating a channel when energized); hence, the quantum dots are defined by voltages applied to the gate electrodes and hence will typically always be in line of sight of a quantum dot-gate. As noted, in one or more embodiments, there is no separate step to ‘form’ the quantum dots other than energizing the gates (i.e., applying a voltage) during operation. Regarding the quantum dot region configured to form a quantum dot when the gate electrode is energized, in one or more embodiments, there is uniformity over the whole chip, and the quantum dot region is part of the substrate adjacent the electrode.

Further regarding the barrier gate(s), in a non-limiting example, if there are two quantum dots next to each other, the barrier can be located “exactly” in the middle. However, a barrier gate can also be located other than exactly in the middle (see comments re overlap below). The barrier gate overlapping the plunger gate electrodes outward of the plunger gate electrodes is acceptable. In accumulation mode, under the plunger gates are located the quantum dots, because the electric field comes from the plunger gates and causes the accumulation. Therefore the quantum dot is underneath the plunger gate. The barrier gate is next to it. The barrier gate does not accumulate, it just lowers the potential barrier between two neighboring quantum dots. For example, form a first gate layer (for the plunger gates) and either oxidize it or deposit an oxide, then form a second gate layer (for the barrier gates).

Comments re overlap: Consider two pertinent concepts: 1. Quantum dots are accumulated by electric fields from the plunger gates into the semiconductor; and 2. Electric fields are screened by metal, so if there is metal between the plunger gate and the semiconductor, it is very difficult to accumulate below. The overlap of the barrier underneath the plunger therefore would simply restrict the quantum dot size, because the electric field from the plunger is screened by the barrier in the overlapping region. The same concept works the other way around if the plunger gate overlaps under the barrier. In this case, the quantum dot is given by the full size of the plunger gate and the barrier gate can effectively tune the barrier only after the plunger gate ends because electric fields from the barrier gates get screened before they reach the semiconductor in the overlapping region. In either situation a little overlap (compared to the overall size of the gates) is not necessarily an issue. It becomes an issue if the overlap is so large that, in one case the barriers restrict the size of the quantum dot too much (then there may be a struggle accumulating the QD correctly), or in the other case, the barrier cannot effectively control the wavefunction overlap (e.g., cannot prevent overlap to switch an interaction between neighboring spins off).

It is worth noting that one or more embodiments can be employed with cryogenic devices (e.g., devices for classical cryogenic computing), since strain can appear, for example, from different thermal expansion coefficients of different materials in a material stack. Such effects can be worse at extreme temperatures, such as cryogenic temperatures.

It will be appreciated that one or more semiconductor structures, according to the teachings herein, may be used in implementing a quantum computer.

Given the teachings herein, for any elements for which example materials are not set forth, the skilled artisan can select appropriate materials, and for any fabrication steps for which specific exemplary processes have not been set forth, the skilled artisan can select appropriate known processes.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1st Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

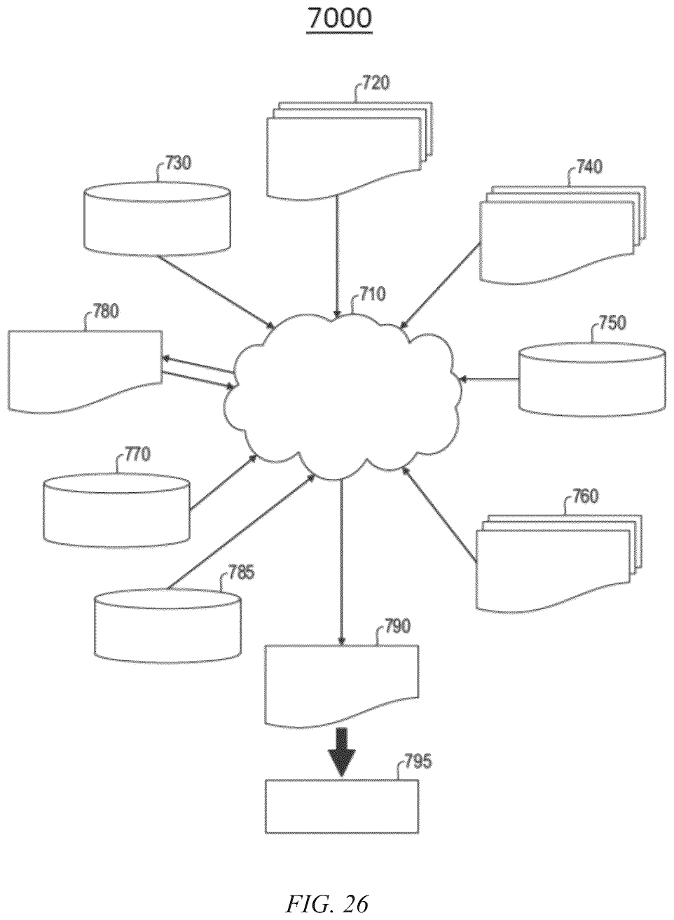

With reference to FIG. 25, a description will now be provided of a computer that could control a digital circuit design synthesis and fabrication process such as in FIG. 26, which could be used to design, synthesize, and fabricate a digital controller and/or other pertinent components.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as a system (see block 200) for semiconductor design and/or control of semiconductor fabrication (see FIG. 26). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 25. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips.

Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing. In such a case, processor set 110 could include a quantum processing unit using strain isolation gaps as described herein.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Exemplary Design Process Used in Semiconductor Design, Manufacture, and/or Test

One or more embodiments make use of computer-aided semiconductor integrated circuit design simulation, test, layout, and/or manufacture. In this regard, FIG. 26 shows a block diagram of an exemplary design flow 7000 used for example, in semiconductor IC logic design, simulation, test, layout, and manufacture. Design flow 7000 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 7000 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 7000 may vary depending on the type of representation being designed. For example, a design flow 7000 for building an application specific IC (ASIC) may differ from a design flow 7000 for designing a standard component or from a design flow 7000 for instantiating the design into a programmable array, for example a programmable gate array (PGA) or a field programmable gate array (FPGA) offered by Altera® Inc. or Xilinx® Inc.

FIG. 26 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design.

Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information.

Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 790 may then proceed to a stage 795 where, for example, design structure 790: proceeds to tape-out, is released to manufacturing, is released to a mask house, is sent to another design house, is sent back to the customer, etc.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a semiconductor substrate;
a gate electrode separated from the semiconductor substrate by a strain isolation gap; and
a quantum dot region formed in the substrate underneath the gate electrode, wherein the quantum dot region is configured to form a quantum dot upon energization of the gate electrode, and wherein the quantum dot is configured to host a spin.

2. The semiconductor structure of claim 1, wherein the gate electrode is a first gate electrode, further comprising a second gate electrode adjacent to the first gate electrode, wherein the first gate electrode is a plunger gate electrode, wherein the second gate electrode is a barrier gate electrode that is also separated from the semiconductor substrate by a strain isolation gap.

3. The semiconductor structure of claim 1, further comprising an anchor, wherein the gate electrode is attached to the semiconductor substrate by the anchor.

4. The semiconductor structure of claim 3, further comprising a dielectric layer interposed between the anchor and the semiconductor substrate, wherein the gate electrode is cantilevered from the anchor and the dielectric layer has a thickness equal to, and defining, the strain isolation gap.

5. The semiconductor structure of claim 4, wherein the gate electrode has a gate electrode diameter, the anchor has an anchor width greater than the gate electrode diameter when viewed in plan, further comprising an attachment portion, the gate electrode being attached to the anchor by the attachment portion, the attachment portion being narrower than the gate electrode diameter when viewed in plan.

6. The semiconductor structure of claim 3, wherein the anchor comprises a first anchor, further comprising a second anchor, wherein the gate electrode is also attached to the semiconductor substrate by the second anchor.

7. The semiconductor structure of claim 6, further comprising a dielectric layer interposed between the first and second anchors and the semiconductor substrate, wherein the gate electrode is suspended between the anchors and the dielectric layer has a thickness equal to, and defining, the strain isolation gap.

8. The semiconductor structure of claim 7, wherein the gate electrode has a gate electrode diameter, the first anchor has a first anchor width greater than the gate electrode diameter when viewed in plan, the second anchor has a second anchor width greater than the gate electrode diameter when viewed in plan, further comprising first and second attachment portions, the gate electrode being respectively attached to the first and second anchors by the first and second attachment portions, the first and second attachment portions being narrower than the gate electrode diameter when viewed in plan.

9. The semiconductor structure of claim 3, wherein the substrate comprises a germanium-on-insulator structure.

10. The semiconductor structure of claim 3, wherein the substrate comprises a silicon-on-insulator structure.

11. The semiconductor structure of claim 3, wherein the substrate comprises bulk germanium.

12. The semiconductor structure of claim 3, wherein the substrate comprises bulk silicon.

13. The semiconductor structure of claim 3, wherein the substrate comprises a compound semiconductor heterostructure with a quantum well.

14. The semiconductor structure of claim 3, wherein the semiconductor substrate is pre-accumulated with either electrons or holes.

15. The semiconductor structure of claim 3, further comprising a voltage source coupled to the gate electrode and a controller coupled to the voltage source, wherein the controller is configured to cause the voltage source to energize the gate electrode to form the quantum dot.

16. A quantum processing unit comprising:
an array of quantum semiconductor structures, wherein each quantum semiconductor structure comprises:
a semiconductor substrate;
a gate electrode separated from the semiconductor substrate by a strain isolation gap; and
a quantum dot region formed in the substrate underneath the gate electrode, wherein the quantum dot region is configured to form a quantum dot upon energization of the gate electrode, and wherein the quantum dot is configured to host a spin;
a voltage source coupled to the gate electrode of each quantum semiconductor structure; and
a controller coupled to the voltage source, wherein the controller is configured to cause the voltage source to selectively energize the gate electrode of each quantum semiconductor structure.

17. The quantum processing unit of claim 16, wherein, for one or more of the semiconductor structures, the gate electrode is a first gate electrode, the one or more of the semiconductor structures further comprising a second gate electrode adjacent to the first gate electrode, wherein the first gate electrode is a plunger gate electrode, wherein the second gate electrode is a barrier gate electrode, and wherein the second gate electrode also is separated from the semiconductor substrate by a strain isolation gap.

18. The quantum processing unit of claim 16, wherein the semiconductor substrate of each semiconductor structure comprises a single common substrate, further comprising at least one anchor for each semiconductor structure and a dielectric layer interposed between the anchors and the semiconductor substrate, wherein the gate electrode for each semiconductor structure is attached to the single common substrate by the anchors, and wherein the single common substrate comprises a compound semiconductor heterostructure with at least one quantum well, wherein the gate electrodes are suspended from the anchors and the dielectric layer has a thickness equal to, and defining, the strain isolation gap.

19. A method of providing strain relief in a quantum processing unit, comprising:
providing a semiconductor structure that includes at least one gate electrode separated from a quantum dot region by a strain isolation gap, wherein the quantum dot region is configured to form a quantum dot upon energization of the gate electrode, and wherein the quantum dot is configured to host a spin; and
inhibiting strain from propagating from the at least one gate electrode into the quantum dot region, using the strain isolation gap.

20. The method of claim 19, further comprising forming the semiconductor structure by:
providing a quantum well with the quantum dot region formed therein;
providing a chip with a gate stack including the at least one gate electrode; and
spacing the chip with the gate stack a predetermined distance from the quantum well, so that the at least one gate electrode is separated from the quantum dot by the strain isolation gap.
